(19) United States
(12) Patent Application Publication
(10) Pub. No.: US 2007/0020531 A1
(43) Pub. Date: Jan. 25, 2007

(54) PHASE SHIFT MASK FOR PATTERNING ULTRA-SMALL HOLE FEATURES

(76) Inventor: Chin-Lung Lin, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/160,918

(22) Filed: Jul. 15, 2005

(51) Int. Cl. G03F 1/00; G03C 5/00; G06F 17/50

(52) U.S. Cl. 430/5; 430/322; 430/324; 716/19

(57) ABSTRACT

A phase shift mask includes a light transparent substrate; an opaque material layer coated on the main surface of the light transparent substrate, wherein the opaque material layer has an window opening exposing a light transparent area of the light transparent substrate; a cruciform first phase shifting region of the exposed light transparent area; and a second phase shifting region of the exposed light transparent area except the cruciform first phase shifting region. Light passing through the cruciform first phase shifting region has a phase shift of 180 degrees relative to light passing through the d second phase shifting region.

### BACKGROUND OF INVENTION

1. Field of the Invention

The present invention relates generally to the field of optical lithography and, more particularly, to a design of phase shift mask (PSM) capable of forming ultra-small, isolated hole pattern on a photo resist layer.

2. Description of the Prior Art

In the circuit making processes, lithographic process has not only been a mandatory technique but also played an important role in limiting feature size. By lithographic process, a wafer producer can precisely and clearly transfer a circuit pattern onto a substrate. In a lithographic process, a designed pattern, such as a circuit pattern or a doping pattern, is created on one or several photo mask, then the pattern on the mask is transferred by light exposure, with a stepper and scanner, onto a substrate. Recently, the most mature lithographic technique is optical lithographic technique, of which the light sources including KrF laser (248 nm), ArF laser (193 nm) and F₂ laser (157 nm) . . . etc., among which KrF laser and ArF laser light exposure techniques are arguably the most developed.

While the traditional technologies continue to advance at breakneck speed they are becoming quite costly and are no longer able to provide the resolution and depth of focus (DOF) with an acceptable process window on their own. This is a direct result of the Sub-Wavelength environment. Fortunately there is an additional knob the industry can adjust to improve the overall system performance. The field of low k₁ lithography includes such techniques as optical proximity correction (OPC), phase shift masks (PSM), off-axis or modified illumination, spatial filters and high contrast resists. These techniques, collectively referred to as Resolution Enhancement Techniques (RETs), work in conjunction with the traditional techniques of decreasing wavelength and increasing NA to extract the highest level of performance possible from the advanced lithography systems.

Central to the resolution enhancement techniques are PSMs. The principle PSMs deployed in the industry include attenuated (usually used for contacts and metal layers) and alternating aperture (used for CD control for gates). However, the conventional designs of the PSMs are still not providing satisfactory results when facing ultra-small, isolated hole patterns.

### SUMMARY OF INVENTION

It is therefore the primary object of the present invention to provide a novel PSM design for ultra-small hole patterning.

According to the claimed invention, a phase shift mask comprises a light transparent substrate having a main surface; an opaque material layer coated on the main surface of the light transparent substrate, wherein the opaque material layer has an window opening exposing a light transparent area of the light transparent substrate; a cruciform first phase shifting region of the exposed light transparent area; and a second phase shifting region of the exposed light transparent area except the cruciform first phase shifting region. Light passing through the cruciform first phase shifting region has a phase shift of 180 degrees relative to light passing through the d second phase shifting region.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic layout diagram demonstrating a portion of a phase shift mask according to one preferred embodiment of the present invention;

FIG. 2 is a schematic, cross-sectional diagram taken from line I-I′ of FIG. 1; and

FIGS. 3-6 are schematic, cross-sectional diagrams demonstrating the exemplary process steps for making the present invention phase shift mask.

### DETAILED DESCRIPTION

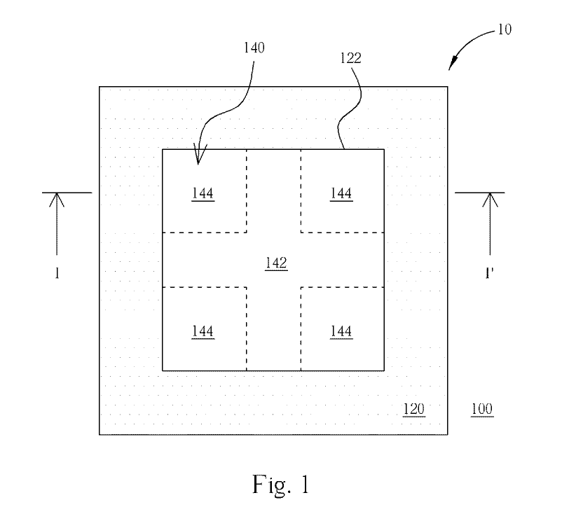

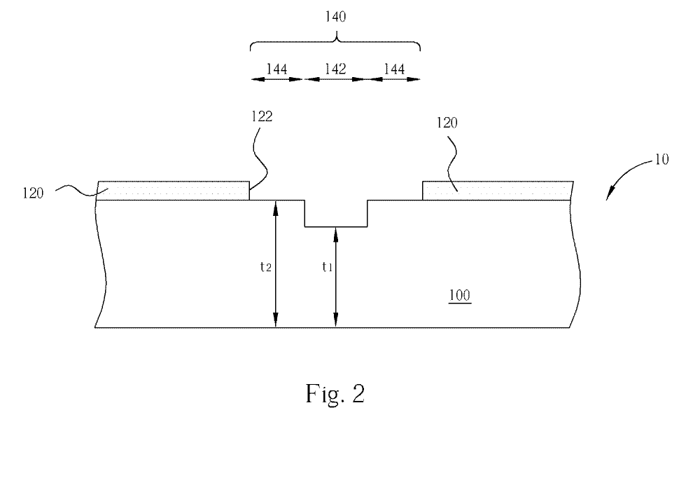

Please refer to FIG. 1 and FIG. 2. FIG. 1 is a schematic layout diagram demonstrating a portion of a phase shift mask 10 according to one preferred embodiment of the present invention. FIG. 2 is a schematic, cross-sectional diagram taken from line I-I′ of FIG. 1. As shown in FIG. 1, the present invention phase shift mask 10 comprises a light transparent substrate 100. The light transparent substrate 100 may be made of light transparent materials such as quartz. On the main surface of the light transparent substrate 100, an opaque material layer 120 such as a chrome layer is coated thereon. The opaque material layer 120 completely blocks the passage of light. The opaque material layer 120 has an opening 122, which exposes a pre-selected light transmission area 140 of the underlying light transparent substrate 100. The pre-selected light transmission area 140 allows light with a specific wavelength to pass therethrough and then project onto a photo resist layer coated on a wafer, thereby forming a ultra-small, isolated hole pattern in the photo resist layer.

The present invention is further characterized in that the light transmission area 140, which is, in accordance with one preferred embodiment, rectangular, includes a cruciform first phase shifting region 142 that is etched into the light transparent substrate 100 to a first substrate thickness t₁. The rectangular light transmission area 140 further includes a second phase shifting region 144, which is just the rest of the exposed light transmission area 140 except the cruciform first phase shifting region 142. As shown in FIG. 2, the second phase shifting region 144 has a second thickness t₂ that is thicker than the first substrate thickness t₁ such that light passing through the cruciform first phase shifting region 142 has a phase shift of 180 degrees relative to light passing through the thicker second phase shifting region 144. As specifically indicated in FIG. 1, the second phase shifting region 144 consists of four independent, rectangular sub-regions disposed at four corners of the rectangular light transmission area 140.

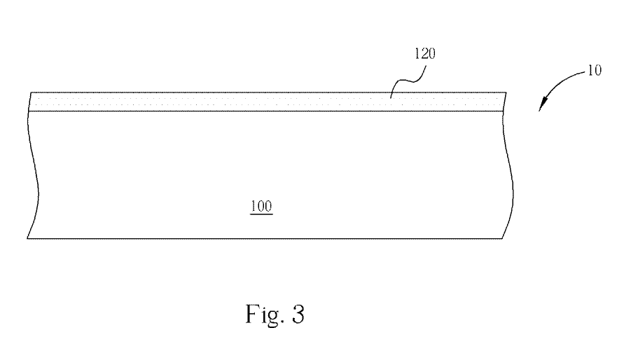

FIGS. 3-6 are schematic, cross-sectional diagrams demonstrating the exemplary process steps for making the present invention phase shift mask 10 as set forth in FIGS. 1-2. Initially, as shown in FIG. 3, a light transparent substrate 100 such as a quartz substrate is provided. An opaque material layer 120 such as a chrome layer is coated on the main surface of the light transparent substrate 100. As previously alluded to, the opaque material layer 120 completely blocks the passage of light.

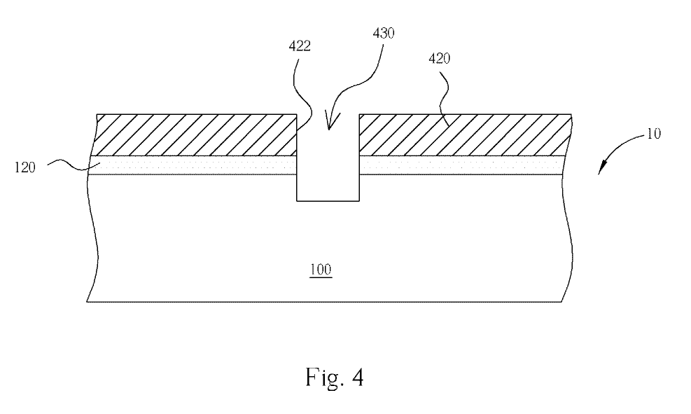

As shown in FIG. 4, a photo resist layer 420 is formed on the opaque material layer 120, followed by a lithographic process to form an opening 422 in the photo resist layer 420. The opening 422 exposes a portion of the underlying opaque material layer 120. Subsequently, through the opening 422, an etching process is carefully carried out to etch the exposed opaque material layer 120 and then continue to etch the light transparent substrate 100 to a depth, thereby forming a recessed region 430. At this phase, the previously mentioned cruciform first phase shifting region 142 is completed.

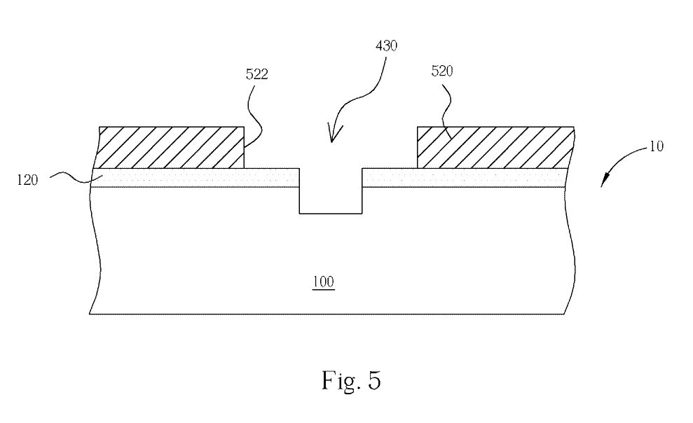

Thereafter, as shown in FIG. 5, the photo resist layer 420 is removed. Another photo resist layer 520 is formed on the opaque material layer 120. A lithographic process is performed to form a rectangular opening 522 in the photo resist layer 520. The rectangular opening 522 exposes the previously formed recessed region 430 and a portion of the opaque material layer 120.

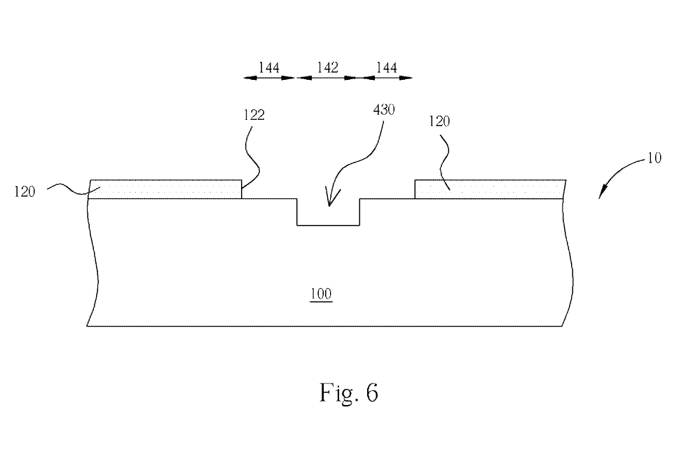

As shown in FIG. 6, using the photo resist layer 520 as a hard mask, the exposed portion of the opaque material layer 120 is selectively etched away through the opening 522, thereby forming an opening 122 in the opaque material layer 120. The photo resist layer 520 is then stripped off.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A phase shift mask, comprising:
a light transparent substrate having a main surface;
an opaque material layer coated on said main surface of said light transparent substrate, wherein said opaque material layer has an window opening exposing a light transparent area of said light transparent substrate;
a cruciform first region of said exposed light transparent area etched into said light transparent substrate to a first substrate thickness; and
a second region of said exposed light transparent area except said cruciform first region, said second region has a second thickness that is thicker than said first substrate thickness such that light passing through said cruciform first region has a phase shift of 180 degrees relative to light passing through said thicker second region.

2. The phase shift mask according to claim 1 wherein said light transparent substrate is a quartz substrate.

3. The phase shift mask according to claim 1 wherein said opaque material layer comprises chrome.

4. The phase shift mask according to claim 1 wherein said opaque material layer completely blocks the passage of light.

5. The phase shift mask according to claim 1 wherein said light transparent area is a rectangular area, and wherein said second region comprises four independent sub-regions disposed at four corners of said rectangular area.

6. The phase shift mask according to claim 5 wherein said independent sub-regions are rectangular.

7. A phase shift mask, comprising:
a light transparent substrate having a main surface;
an opaque material layer coated on said main surface of said light transparent substrate, wherein said opaque material layer has an window opening exposing a light transparent area of said light transparent substrate;
a cruciform first phase shifting region of said exposed light transparent area; and
a second phase shifting region of said exposed light transparent area except said cruciform first phase shifting region, wherein light passing through said cruciform first phase shifting region has a phase shift of 180 degrees relative to light passing through said second phase shifting region.

8. The phase shift mask according to claim 7 wherein said light transparent substrate is a quartz substrate.

9. The phase shift mask according to claim 7 wherein said opaque material layer comprises chrome.
